(19) United States
(12) Patent Application Publication
(10) Pub. No.: US 2012/0039495 A1
(43) Pub. Date: Feb. 16, 2012

(54) AUDIO PROCESSING APPARATUS, AUDIO PROCESSING METHOD, AND PROGRAM

(75) Inventor: Eiji ONO, Tokyo (JP)

(73) Assignee: SONY CORPORATION, Tokyo (JP)

(21) Appl. No.: 13/182,938

(22) Filed: Jul. 14, 2011

(30) Foreign Application Priority Data
Aug. 13, 2010 (JP) 2010-181269

(51) Int. Cl. H03B 29/00; H04R 5/02; H03G 9/14

(52) U.S. Cl. 381/309; 381/102; 381/71.1

(57) ABSTRACT

An audio processing apparatus is disclosed which includes: a first signal generation portion configured to generate an audio signal of which the frequency is varied over time; an operation portion; a storage portion configured to store characteristic information in accordance with the frequency and an amplitude of the audio signal in effect when the operation portion is operated; a reproduction portion configured to reproduce audio data; and a correction portion configured to correct a reproduced signal from the reproduction portion based on the characteristic information stored in the storage portion.

### BACKGROUND

The present disclosure relates to an audio processing apparatus, an audio processing method, and a program.

The recent years have witnessed widespread use of audio reproduction apparatuses capable of reproducing audio data. Also, there has been proposed an audio reproduction apparatus furnished with a noise canceling function of reducing noise components by outputting through earphones or headphones an audio signal with its phase opposite to that of the ambient noise, as described in Japanese Patent Laid-Open No. Hei 9-187093 (called Patent Document 1 hereunder) for example.

There are other audio reproduction apparatuses capable of acquiring a user's hearing characteristics and reproducing audio data by automatically equalizing the data in keeping with the acquired hearing characteristics of the user. For example, the audio reproduction apparatus may successively output test tones at different frequencies with their sound volumes varied over time, and acquire as the user's hearing characteristics the sound volume in effect upon user operation performed on each test tone. The audio reproduction apparatus may then adjust the frequency characteristics of a reproduced signal in accordance with the user's hearing characteristics acquired, whereby the user can perceive the original sound image based on the audio data. One such audio reproduction apparatus is disclosed in Japanese Patent Laid-Open No. Hei 6-217389 (called Patent Document 2 hereunder).

### SUMMARY

Typically, the acquisition of hearing characteristics is but one of the steps in carrying out automatic equalization and thus can pose a problem in terms of usability if the step is too time-consuming. Moreover, the hearing characteristic tests using test tones with only their sound volumes varied over time can be too stale to sustain the user's willingness to perform the tests.

The present disclosure has been made in view of the above circumstances and provides an audio processing apparatus, an audio processing method, and a program innovated and improved to provide the user with freshly inspired hearing characteristic tests.

According to one embodiment of the present disclosure, there is provided an audio processing apparatus including: a first signal generation portion configured to generate an audio signal of which the frequency is varied over time; an operation portion; a storage portion configured to store characteristic information in accordance with the frequency and an amplitude of the audio signal in effect when the operation portion is operated; a reproduction portion configured to reproduce audio data; and a correction portion configured to correct a reproduced signal from the reproduction portion based on the characteristic information stored in the storage portion.

Preferably, the audio processing apparatus of the present disclosure may further include: a sound pickup portion; a second signal generation portion configured to generate an ambient sound reduction signal for reducing an ambient sound based on the pickup of the ambient sound by the sound pickup portion; and a control portion configured to control the second signal generation portion in operation; wherein the control portion may operate the second signal generation portion while the first signal generation portion is being caused to generate the audio signal.

Preferably, the second signal generation portion may generate the ambient sound reduction signal different in frequency characteristic from the ambient sound in accordance with the frequency of the audio signal generated by the first signal generation portion.

Preferably, the second signal generation portion may generate the ambient sound reduction signal in a manner rendering the ambient sound lower on the same frequency band as the audio signal generated by the first signal generation portion than on other frequency bands.

Preferably, the first signal generation portion may generate the audio signal of which not only the frequency but also the amplitude is varied over time.

Preferably, the control portion may control whether or not to operate the second signal generation portion upon reproduction of the audio data by the reproduction portion.

Preferably, if the second signal generation portion does not generate the ambient sound reduction signal, the correction portion may correct the reproduced signal from the reproduction portion in accordance with the characteristic information stored in the storage portion and in keeping with the ambient sound picked up by the sound pickup portion.

Preferably, the correction portion may emphasize the reproduced signal on the same frequency band as the ambient sound.

Preferably, when operating upon reproduction of the audio data by the reproduction portion, the second signal generation portion may generate the ambient sound reduction signal based on the characteristic information stored in the storage portion.

Preferably, the audio processing apparatus according to the embodiment of the present disclosure may further include a left-ear audio output portion and a right-ear audio output portion; wherein the storage portion may store left-ear characteristic information and right-ear characteristic information; and the correction portion may correct the reproduced signal output to the left-ear audio output portion in accordance with the left-ear characteristic information and the reproduced signal output to the right-ear audio output portion in keeping with the right-ear characteristic information.

Preferably, the audio processing apparatus according to the embodiment of the present disclosure may further include a display portion configured to display a screen in accordance with the characteristic information having been acquired.

Preferably, the storage portion may store the audio data based on the reproduced signal having undergone the correction by the correction portion.

According to another embodiment of the present disclosure, there is provided a program for causing a computer to function as an apparatus including: a first signal generation portion configured to generate an audio signal of which the frequency is varied over time; an operation portion; a storage portion configured to store characteristic information in accordance with the frequency and an amplitude of the audio signal in effect when the operation portion is operated; a reproduction portion configured to reproduce audio data; and a correction portion configured to correct a reproduced signal from the reproduction portion based on the characteristic information stored in the storage portion.

According to a further embodiment of the present disclosure, there is provided an audio processing method including: generating an audio signal of which the frequency is varied over time; storing onto a storage medium characteristic information in accordance with the frequency and an amplitude of the audio signal in effect when a user performs an operation; reproducing audio data; and correcting a reproduced signal of the audio data based on the characteristic information stored on the storage medium.

According to the embodiments of the present disclosure outlined above, it is possible to provide the user with freshly inspired hearing characteristic tests.

### BRIEF DESCRIPTION OF THE DRAWINGS

FIG. 1 is an explanatory view showing an external appearance of an audio processing apparatus according to an embodiment of the present disclosure;

FIG. 2 is an explanatory view showing results of a comparative example of hearing characteristic tests;

FIG. 3 is a functional block diagram showing a typical structure of an audio processing apparatus as a first embodiment of the present disclosure;

FIG. 4 is an explanatory view showing a typical structure of a test tone generation circuit;

FIG. 5 is an explanatory view showing a specific example of test tones generated by a sine wave generation circuit;

FIG. 6 is an explanatory view showing a specific example of hearing characteristic information;

FIG. 7 is a flowchart showing how the audio processing apparatus as the first embodiment typically operates;

FIG. 8 is an explanatory view showing a variation of the test tone;

FIG. 9 is an explanatory view showing how the test tone variation is typically generated;

FIG. 10 is another explanatory view showing how the test tone variation is typically generated;

FIG. 11 is another explanatory view showing how the test tone variation is typically generated;

FIG. 12 is another explanatory view showing how the test tone variation is typically generated;

FIG. 13 is another explanatory view showing how the test tone variation is typically generated;

FIG. 14 is another explanatory view showing how the test tone variation is typically generated;

FIG. 15 is a functional block diagram showing a typical structure of an audio processing apparatus as a second embodiment of the present disclosure;

FIG. 16 is an explanatory view showing a typical structure of a noise canceling sound generation circuit;

FIG. 17 is an explanatory view showing how the frequency characteristic of a noise canceling sound is typically varied;

FIG. 18 is a functional block diagram showing a typical structure of an audio processing apparatus as a third embodiment of the present disclosure; and

FIG. 19 is an explanatory view showing a specific example of hearing characteristic test results displayed on a screen by a display portion.

### DETAILED DESCRIPTION OF THE PREFERRED EMBODIMENTS

Some preferred embodiments of the present disclosure will now be described in detail with reference to the accompanying drawings. Throughout this specification and the accompanying drawings, like reference characters designate like or corresponding components, and their explanations may be omitted where redundant.

Also in this specification and the accompanying drawings, a plurality of components that are substantially the same functionally and structurally may be distinguished from one another by having their common reference character supplemented with different alphabetical characters. If there is no specific need to distinguish such multiple components having substantially the same function and structure, they will be accompanied solely by their common reference character.

The ensuing description of the preferred embodiments will be given under the following headings:

1. Basic structure of the audio processing apparatus;
2. First embodiment;

2-1. Structure of the audio processing apparatus as the first embodiment;

2-2. Operations of the audio processing apparatus as the first embodiment;

2-3. Test tone variation;

3. Second embodiment;
4. Third embodiment;

### 5. Variations; and

### 6. Conclusion.

### 1. BASIC STRUCTURE OF THE AUDIO PROCESSING APPARATUS

The present disclosure may be implemented in diverse embodiments as will be explained below under the headings of “2. First embodiment” through “4. Third embodiment” for example. An audio processing apparatus 20 on which the embodiments are based includes:

(1) a first signal generation portion (test tone generation circuit 220) for generating an audio signal (test tones) of which the frequency is varied over time;
(2) an operation portion 24; and
(3) a storage portion 230 for storing characteristic information corresponding to the frequencies and amplitudes of the audio signal in effect when the operation portion is operated.

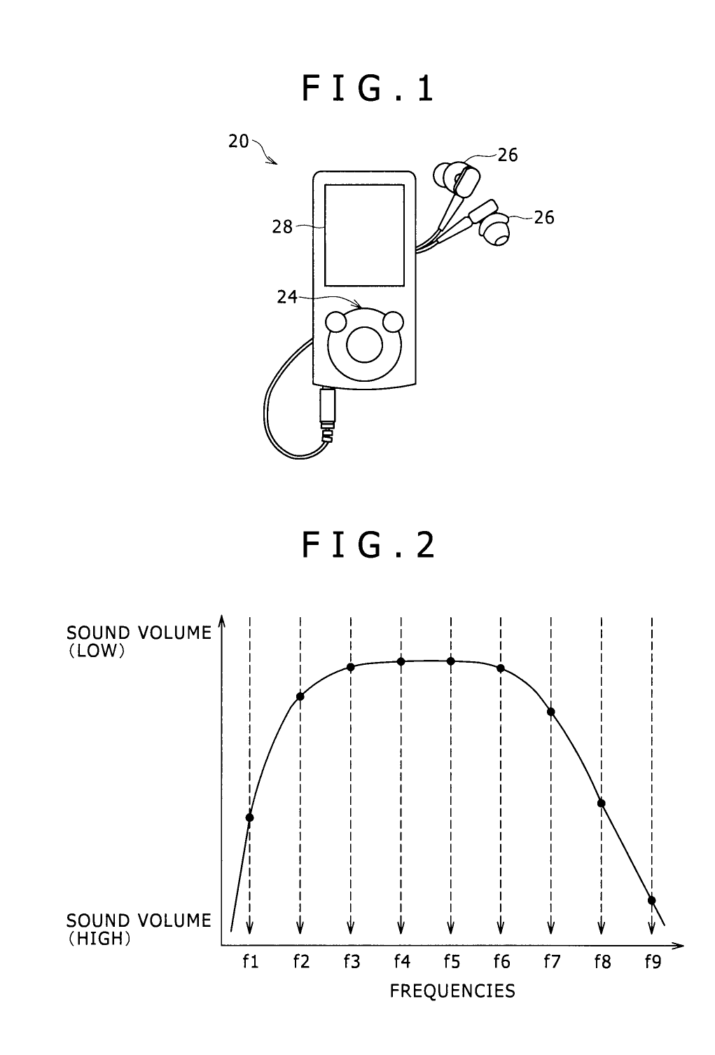

Described below in reference to FIG. 1 is the basic structure such as one outlined above and common to the diverse embodiments of the present disclosure.

FIG. 1 is an explanatory view showing an external appearance of the audio processing apparatus 20 according to an embodiment of the present disclosure. As shown in FIG. 1, the audio processing apparatus 20 includes an operation portion 24, earphones 26, and a display portion 28.

The display portion 28 displays diverse screens such as a menu screen and a reproduction selection screen for guiding user operations; screens for displaying attribute information including title names, artist names and/or genres of audio data; and screens for indicating audio data reproduction status. The display portion 28 may be a liquid crystal display (LCD) device, an organic light-emitting diode (OLED) device, or some other suitable display device.

The operation portion 24 is structured to accept the operation instructions and information input by the user. For example, by operating the operation portion 24, the user can input instructions such as those for selecting audio data, for starting reproduction, for pausing, and for fast-forwarding to the audio processing apparatus 20. Also, the embodiment allows the user to perform hearing characteristic tests by operating the operation portion 24. The operation portion 24 is not limited to any specific form. For example, the operation portion 24 may be composed of a mouse, a keyboard, a touch panel, buttons, and/or switches.

The earphones 26 function as an audio output portion for outputting the reproduced signal of audio data. Also, the earphones 26 output test tones for acquiring the user's hearing characteristics. Although FIG. 1 indicates the audio output portion in the form of the earphones 26 for example, the audio output portion may be structured alternatively in the form of speakers or headphones.

Whereas FIG. 1 shows a portable audio reproduction apparatus as an example of the audio processing apparatus 20, the audio processing apparatus 20 is not limited to that example. Alternatively, the audio processing apparatus 20 may be any one of information processing apparatuses including PC's (personal computers), home-use video processing apparatuses (DVD recorder, video cassette recorder, etc.), PDA's (personal digital assistants), home-use videogame consoles, household electrical appliances, mobile phones, and portable videogame machines.

What is particularly innovative of the audio processing apparatus 20 embodying the present disclosure is the manner in which hearing characteristic tests are carried out thereby. In the ensuing description, a comparative example of hearing characteristic tests will be explained first, followed by detailed explanations of the preferred embodiments of the present disclosure under the headings of “2. First embodiment” through “4. Third embodiment.”

### (Comparative Example of Hearing Characteristic Tests)

In the comparative example of hearing characteristic tests, test tones are output successively at different frequencies with their sound volumes varied over time. The sound volume in effect when the user has performed an operation on each of the test tones involved is acquired as the user's hearing characteristics. The example is explained below in more detail with reference to FIG. 2.

FIG. 2 is an explanatory view showing results of the comparative example of hearing characteristic tests. In FIG. 2, broken lines denote test tones, and a solid line represents the user's hearing characteristics. As indicated in FIG. 2, the comparative example of hearing characteristic tests involves successively outputting test tones at frequencies f1 through f9 with their sound volumes increased over time. The sound volume in effect when the user has performed an operation on each test tone is acquired as the user's hearing characteristics.

One disadvantage of the comparative example above of hearing characteristic tests is that it takes a long time to acquire detailed hearing characteristics because of the numerous test tones to be output. The hearing characteristic tests are but one of the steps in carrying out automatic equalization and thus can pose a problem in terms of usability if this step is too time-consuming. Moreover, the hearing characteristic tests using test tones with only their sound volumes varied over time can be too stale to sustain the user's willingness to perform the tests.

Another disadvantage of the above-described comparative example of hearing characteristic tests is that the user's hearing characteristics acquired thereby can be affected by external noise. In particular, low frequencies constitute a frequency range that is inherently difficult for humans to hear. In an environment where there exists external noise containing numerous low-frequency components, low-frequency test tones can be buried in the noise. In that case, exact hearing characteristics are difficult to acquire. Ideally, hearing characteristic tests should be performed in an anacoustic chamber where there is no external noise. However, using the anacoustic chamber solely for the purpose of hearing characteristic tests is not a realistic option.

The embodiments of the present disclosure have been created in part with a view to overcoming the above disadvantages of the comparable techniques. In carrying out the present disclosure, a first embodiment thereof envisages providing the user with freshly inspired hearing characteristic tests while reducing the time required to perform the tests. A second embodiment of the present disclosure is implemented to perform the hearing characteristic tests while minimizing the effects of external noise. A third embodiment of the present disclosure is implemented to let the user recognize his or her own hearing characteristics. What follows is a detailed description of the audio processing apparatus 20 practiced as each of these embodiments.

### 2. FIRST EMBODIMENT

### (2-1. Structure of the Audio Processing Apparatus as the First Embodiment)

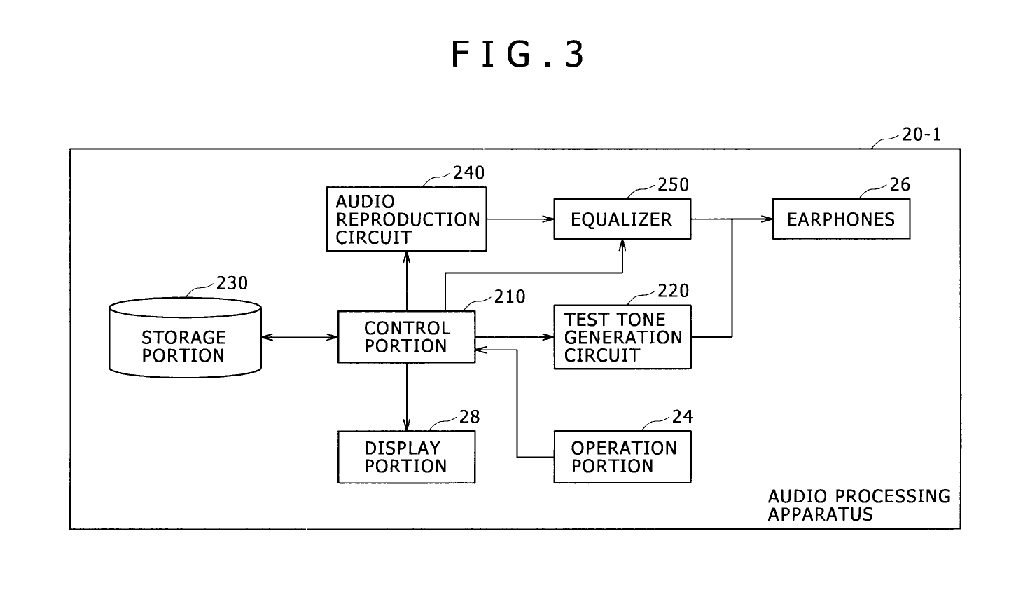

FIG. 3 is a functional block diagram showing a typical structure of an audio processing apparatus 20-1 as the first embodiment of the present disclosure. As shown in FIG. 3, the audio processing apparatus 20-1 as the first embodiment is made up of an operation portion 24, earphones 26, a display portion 28, a control portion 210, a test tone generation circuit 220, a storage portion 230, an audio reproduction circuit 240, and an equalizer 250.

The control portion 210 controls the overall performance of the audio processing apparatus 20-1. For example, the control portion 210 controls the operation of the equalizer 250, display of the display portion 28, and test tone generation of the test tone generation circuit 220.

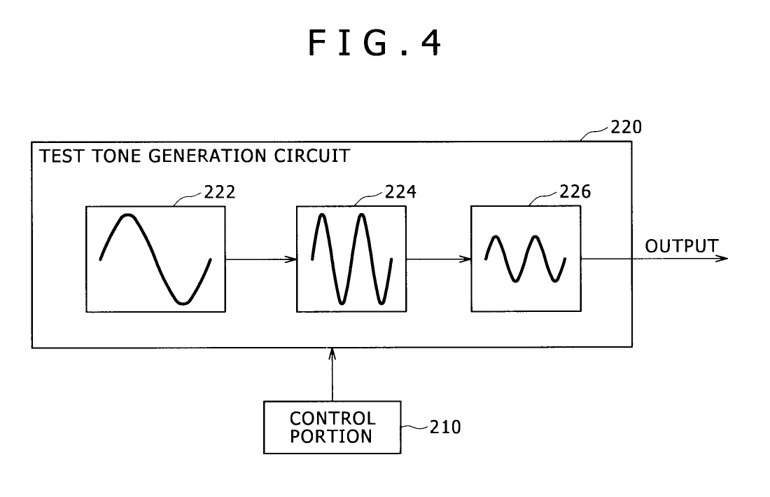

Under control of the control portion 210, the test tone generation circuit 220 generates test tones with their frequencies varied over time. The test tone generation circuit 220 is explained below in detail with reference to FIG. 4.

FIG. 4 is an explanatory view showing a typical structure of the test tone generation circuit 220. As shown in FIG. 4, the test tone generation circuit 220 is composed of a sine wave generation circuit 222, a frequency modulation circuit 224, and an amplitude adjustment circuit 226.

The sine wave generation circuit 222 generates a sine wave serving as the basis for the test tones to be used in hearing characteristic tests. The frequency modulation circuit 224 modulates the frequency of the sine wave generated by the sine wave generation circuit 222 in accordance with a control signal from the control portion 210. The amplitude adjustment circuit 226 adjusts the amplitude of the sine wave output from the frequency modulation circuit 224 in keeping with a control signal from the control portion 210.

Test tones are then generated by the test tone generation circuit 220 and fed to the earphones 26 for output as a sound. Although FIG. 4 shows the amplitude adjustment circuit 226 disposed downstream of the frequency modulation circuit 224, this is merely an example. Alternatively, the amplitude adjustment circuit 226 may be located upstream of the frequency modulation circuit 224.

The above-described sine wave generation circuit 222 regulates the frequency and amplitude of the sine wave dynamically so as to generate test tones, i.e., sweep tones with at least their frequencies varied over time. Explained below in reference to FIG. 5 is a specific example of the test tones generated by the sine wave generation circuit 222.

FIG. 5 is an explanatory view showing a specific example of test tones generated by the test tone generation circuit 222. In FIG. 5, broken lines denote test tones, and a solid line represents the user's hearing characteristics detected (previous characteristics are unknown). As illustrated in FIG. 5, the sine wave generation circuit 222 generates a plurality of test tones of which the frequencies are increased while their sound volumes (i.e., amplitudes) are kept constant. For example, the sine wave generation circuit 222 generates successively the test tones ranging from a tone with a sound volume V1 to a tone with a sound volume V6.

Upon hearing each of these test tones, the user operates the operation portion 24. For example, the user may press the operation portion 24 the moment a test tone is heard. Alternatively, the user may keep pressing the operation portion 24 while a test tone is being heard. As another alternative, the user may press the operation portion 24 the moment a test tone stops being heard. As a further alternative, the user may keep pressing the operation portion 24 while a test tone is not being heard.

It is assumed here that the user keeps pressing the operation portion 24 while a test tone is being heard. On that assumption, given the test tone with the sound volume V1 shown in FIG. 5, the user keeps pressing the operation portion 24 while the frequency of the test tone being heard ranges from F1 to F12. In this case, it may be determined that a sound volume V1/frequency F1 combination in effect when the user performs an operation (i.e., pressing the operation portion) and a sound volume V1/frequency F12 combination in effect when the user performs another operation (i.e., releasing the operation portion) constitute the boundaries delimiting the user's audible and inaudible ranges. Thus the sound volume V1/frequency F1 combination and sound volume V1/frequency F12 combination are recorded to the storage portion 230 as the user's hearing characteristic information.

As discussed above, the first embodiment of the present disclosure is efficient in that it can acquire a plurality of items of hearing characteristic information using a single test tone. The user's hearing characteristic information is acquired likewise regarding the other test tones and is recorded to the storage portion 230.

For example, the test tone with the sound volume V1 has its frequencies F1 and F12 widely apart from each other as shown in FIG. 5. Consequently, if the test tone frequency is varied at a constant speed, then it may take a long time for the frequency to change from F1 to F12. In such a case, the control portion 210 may arrange to raise the rate at which the frequency is varied within a frequency range where the user is highly likely to hear the test tone based on the average hearing characteristic model. This arrangement can reduce the time it takes to carry out the hearing characteristic tests.

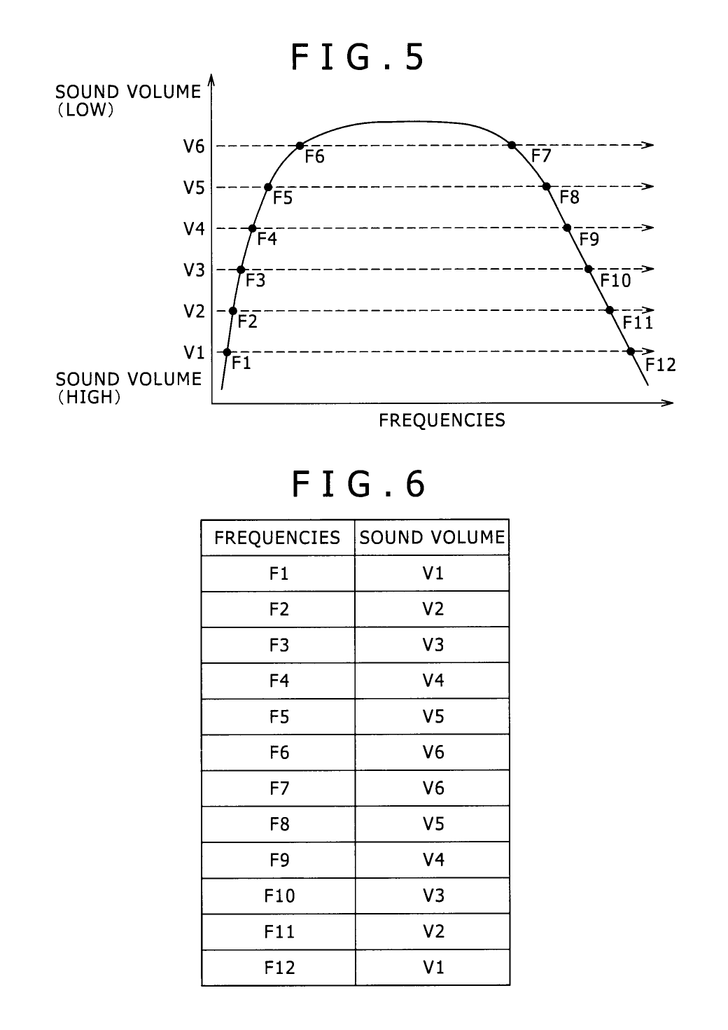

The storage portion 230 stores diverse content data such as audio data as well as the user's hearing characteristic information acquired through hearing characteristic tests. A specific example of hearing characteristic information is explained below in reference to FIG. 6.

FIG. 6 is an explanatory view showing a particular example of hearing characteristic information. As shown in FIG. 6, the storage portion 230 stores the relations between frequencies and sound volumes as hearing characteristic information. Although FIG. 6 shows an example in which the frequencies and sound volumes in effect when the user performed operations during hearing characteristic tests are stored unchanged in the storage portion 230, this is not limitative of the first embodiment. Alternatively, the control portion 210 may mathematize the relations between the frequencies and volumes in effect when the user performed operations on each of the test tones involved and store the mathematized hearing characteristic information into the storage portion 230.

The storage portion 230 may be any one of such storage media as nonvolatile memories, magnetic disks, optical disks, and MO (Magneto-Optical) disks. The nonvolatile memories include EEPROM (Electrically Erasable Programmable Read-Only Memory), EPROM (Erasable Programmable ROM) for example. The magnetic disks include hard disks and other disk-shaped magnetic bodies. The optical disks include CD (Compact Disc), DVD-R (Digital Versatile Disc Recordable), and BD (Blu-Ray Disc (registered trademark)).

The audio reproduction circuit 240 (reproduction portion) shown in FIG. 3 reads audio data from the storage portion 230 or obtains audio data from the outside and reproduces the audio data thus retrieved or acquired. During its reproducing process, the audio reproduction circuit 240 may expand compressed audio data and convert the audio data from digital to analog form, for example.

In accordance with a control signal from the control portion 210, the equalizer 250 (correction portion) corrects the frequency characteristic of a reproduced signal from the audio reproduction circuit 240 and forwards the corrected reproduced signal to the earphones 26. More specifically, based on the user's hearing characteristic information stored in the storage portion 230, the control portion 210 supplies the equalizer 250 with the control signal for emphasizing or deemphasizing particular frequency bands. In keeping with the control signal from the control portion 210, the equalizer 250 may emphasize the frequency band where the user's hearing is low and deemphasize the frequency components of which the user's hearing is high enough. Also, the equalizer 250 performs overall sound quality correction (averaging) and enhancement (clarification of the sound image).

The first embodiment of the present disclosure, as explained above, permits execution of hearing characteristic tests using the test tones of which the frequencies are varied over time. By correcting the reproduced signal of audio data in accordance with the user's hearing characteristic information acquired through the hearing characteristic tests, the first embodiment allows the user to perceive the original sound image based on the corrected audio data.

### (2-2. Operations of the Audio Processing Apparatus as the First Embodiment)

The foregoing paragraphs discussed the typical structure of the audio processing apparatus 20-1 practiced as the first embodiment of the present disclosure. What follows is an explanation of how the audio processing apparatus 20-1 as the first embodiment typically operates.

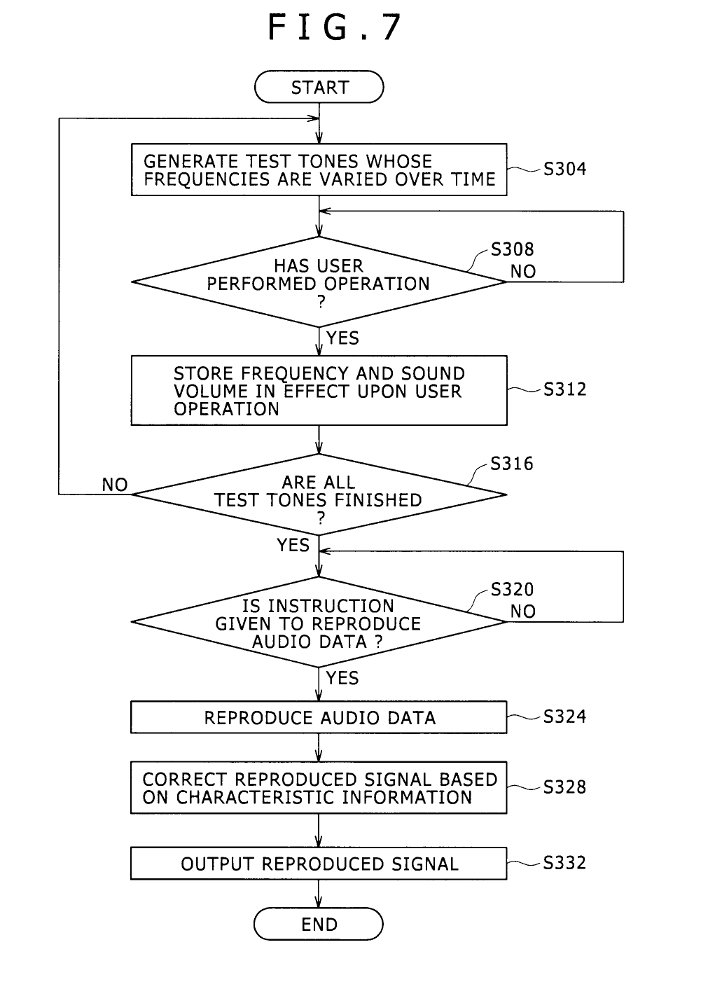

FIG. 7 is a flowchart showing typical operations of the audio processing apparatus 20-1 as the first embodiment. As shown in FIG. 7, the test tone generation circuit 220 first generates a test tone of which the frequency is varied over time (in step S304).

If the user operates the operation portion 24 (in step S308), the storage portion 230 stores the frequency and sound volume in effect when the user performed the operation (in step S312). The audio processing apparatus 20-1 repeats steps S304 through S312 until all test tones have been processed and finished (in step S316).

Then if the user gives an instruction to reproduce audio data by means of the operation portion 24 (in step S320), the audio reproduction circuit 2490 starts reproducing the audio data (in step S324). The equalizer 250 corrects the reproduced signal from the audio reproduction circuit 240 based on the user's hearing characteristic information stored in the storage portion 230 (in step S328). The reproduced signal corrected by the equalizer 250 is output from the earphones 26 (in step S332).

### (2-3. Test Tone Variation)

The foregoing paragraphs discussed the audio processing apparatus 20-1 as the first embodiment of the present disclosure, the apparatus being shown to use the test tones of which the frequencies are varied over time. However, the test tones used by the audio processing apparatus 20-1 for hearing characteristic tests are not limited to those of which the frequencies alone are varied over time as illustrated in FIG. 5. Alternatively, the audio processing apparatus 20-1 may generate a test tone of which, as well as the frequency, the sound volume is varied over time. Described below is a specific example of such a test tone as well as a typical method for generating that test tone.

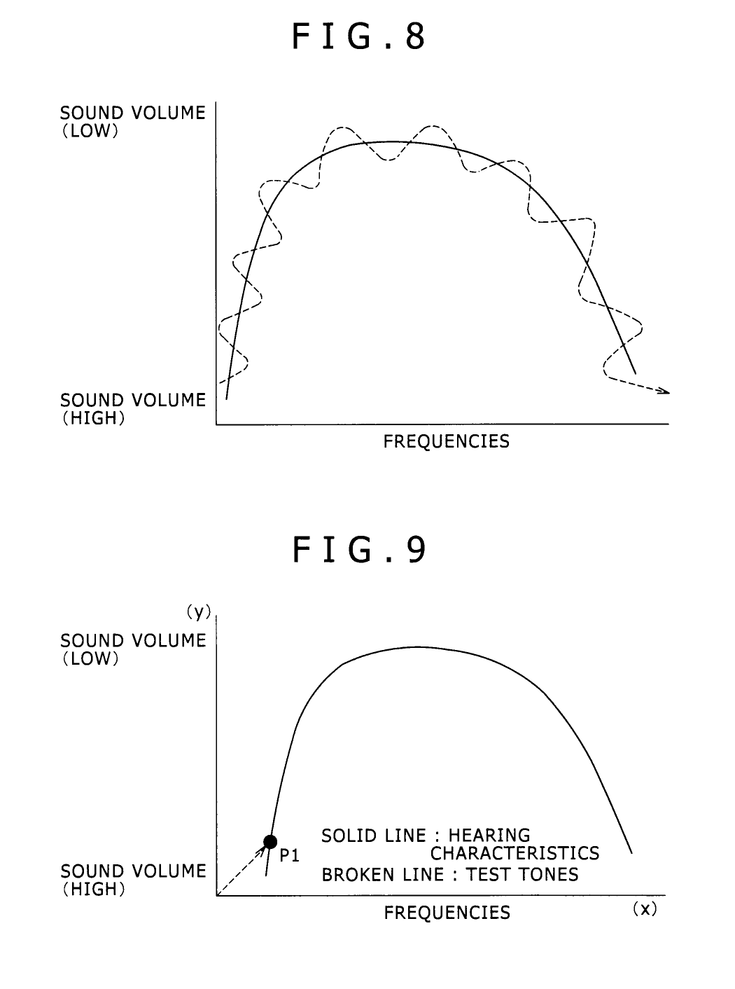

FIG. 8 is an explanatory view showing a variation of the test tone. In FIG. 8, a broken line denotes the test tone and a solid line represents the user's hearing characteristics detected (previous characteristics are unknown). The test tone generation circuit 220 can generate a test tone that changes vibrationally on the frequency-sound volume plane in keeping with the predicted hearing characteristics of the user. Using this test tone permits efficient acquisition of the user's detailed hearing characteristic information. A typical method for generating such a test tone is explained below in reference to FIGS. 9 through 14.

FIGS. 9 through 14 are explanatory views showing how the above-described test tone variation is typically generated. First, in accordance with a control signal from the control portion 210, the test tone generation circuit 220 varies the frequency and sound volume of a generated test tone in such a manner that the test tone plots a straight line with a gradient on the x-y plane (i.e., frequency-volume plane) as shown in FIG. 9.

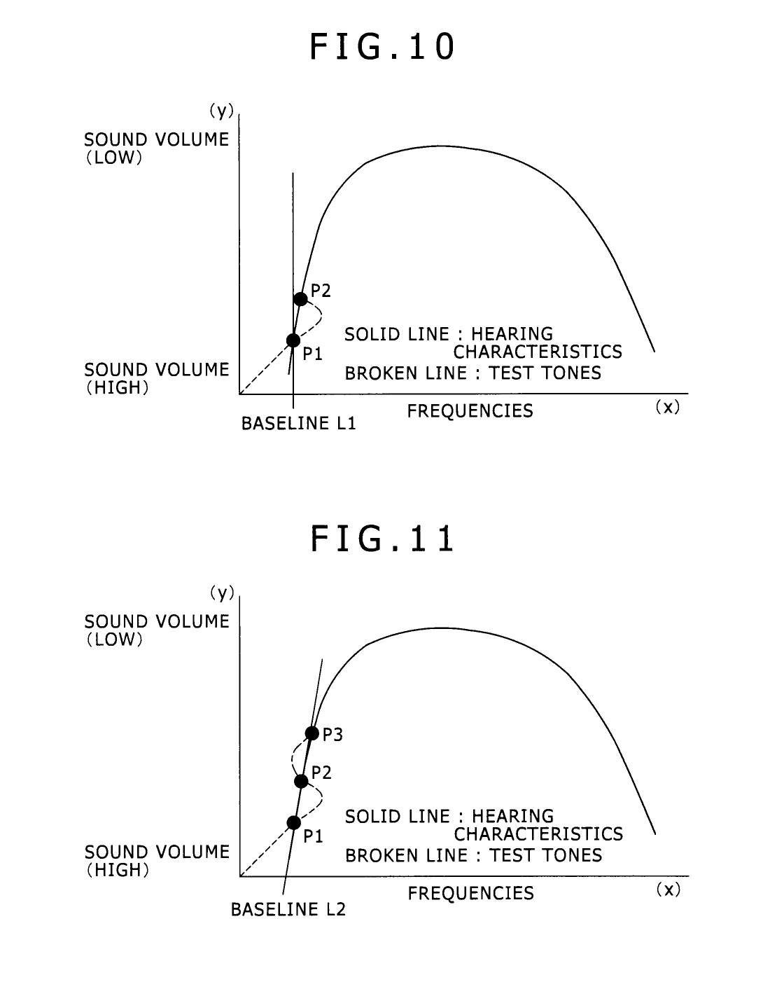

When the user performs an operation at point P1, the test tone generation circuit 220 varies the frequency and sound volume of the test tone in such a manner that the test tone plots a sine wave with its baseline (L1) taken along a line parallel to the y-axis and with its origin taken at point P1, as shown in FIG. 10. When the user performs another operation at point P2, the test tone generation circuit 220 varies the frequency and sound volume of the test tone in such a manner that the test tone plots a sine wave with its baseline (L2) taken along a line connecting points P1 (first point) and P2 (second point) and with its origin taken at point P2, as shown in FIG. 11.

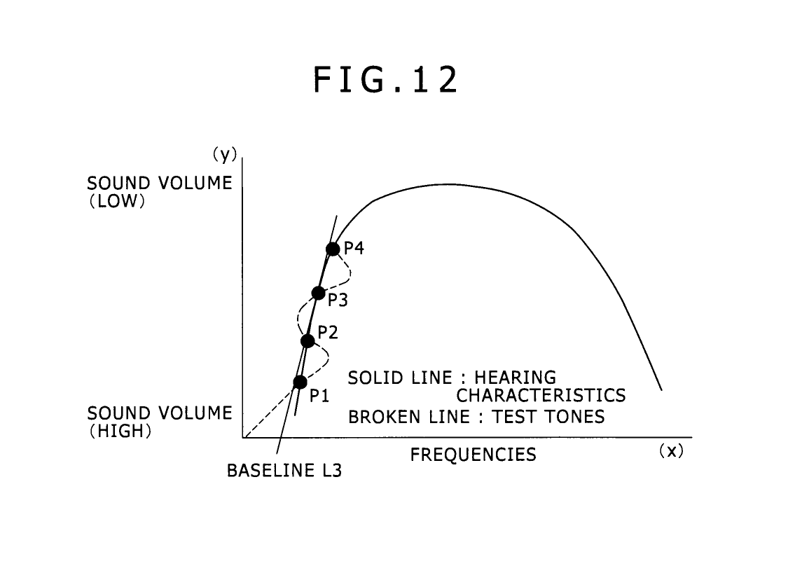

When the user performs yet another operation at point P3, the test tone generation circuit 220 varies the frequency and sound volume of the test tone in such a manner that the test tone plots a sine wave with its baseline (L3) taken along a line whose gradient is obtained by adding up the gradient of the line connecting points P2 and P3 and the difference between the gradient of the line connecting points P1 and P2 and the gradient of the line connecting points P2 and P3, and with its origin taken at point P3, as shown in FIG. 12.

In like manner, when the user performs an operation at point Pn, the test tone generation circuit 220 varies the frequency and sound volume of the test tone in such a manner that the test tone plots a sine wave with its baseline (Ln) taken along a line whose gradient is obtained by adding up the gradient of the line connecting points Pn and Pn−1 and the difference between the gradient of the line connecting points Pn and Pn−1 and the gradient of the line connecting points Pn−1 and Pn−2, and with its origin taken at point Pn.

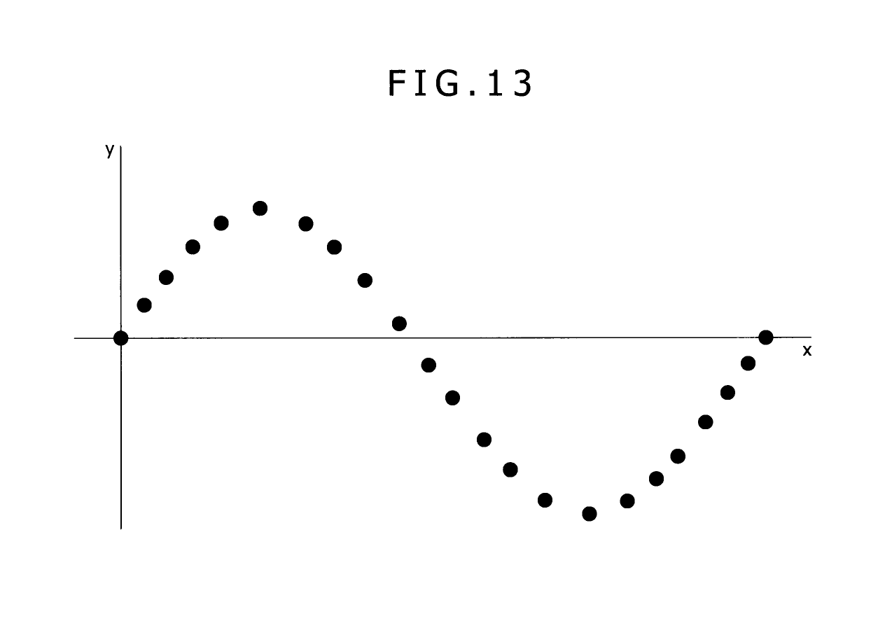

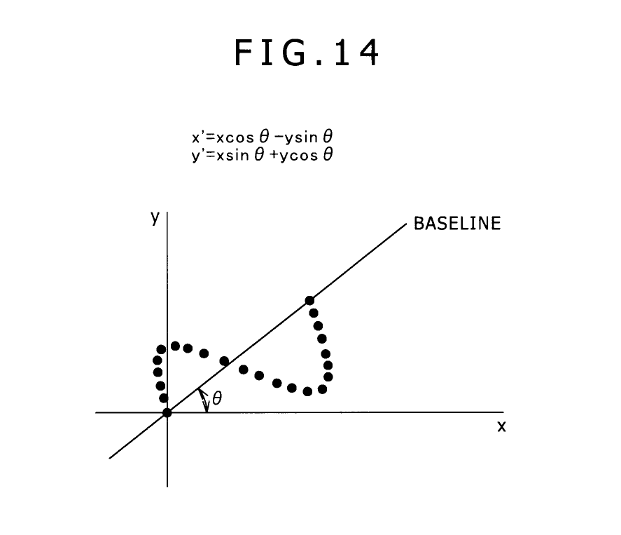

Below is a supplementary explanation of the relations between the baselines and the sine wave, with reference to FIGS. 13 and 14. As shown in FIG. 13, the audio processing apparatus 20-1 is arranged to store beforehand the coordinates of the plotted positions constituting the sine wave. If the gradient of the baseline is θ, the control portion 210 rotates by the gradient θ each of the plotted positions making up the sine wave as illustrated in FIG. 14. If the coordinates of each plotted position before the rotation are (x, y), then the coordinates of each plotted position after the rotation (x′, y′) are expressed by the following mathematical expressions:

x′=x cos θ−y sin θ

y′=y sin θ+y cos θ

Thereafter, the control portion 210 moves the origin of the rotated sine wave to the point where the user performed an operation, and provides the test tone generation circuit 220 with a control signal designating the frequency and sound volume corresponding to each of the plotted positions constituting the moved sine wave. This allows the test tone generation circuit 220 to generate a test tone that changes vibrationally on the frequency-volume plane as shown in FIG. 8. The control portion 210 performs the above-described process based on the sine wave whose phase is inverted every time the user performs the operation anew.

### 3. SECOND EMBODIMENT

The foregoing paragraphs discussed the audio processing apparatus 20-1 as the first embodiment of the present disclosure. What follows is an explanation of an audio processing apparatus 20-2 practiced as the second embodiment of the present disclosure. As will be discussed below in detail, the audio processing apparatus 20-2 as the second embodiment is capable of performing hearing characteristic tests while suppressing the influence of external noise.

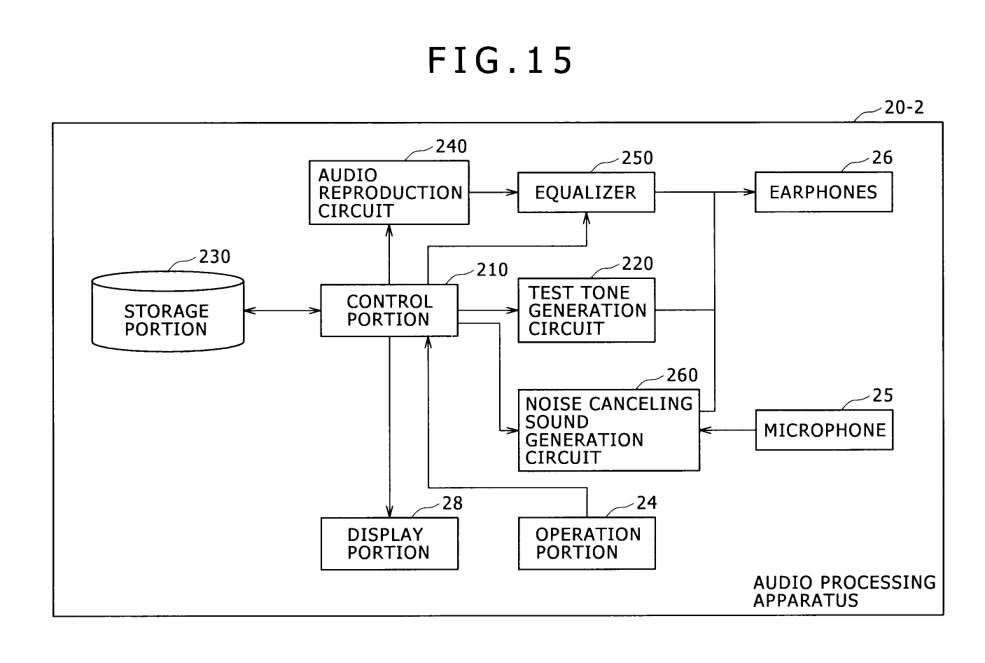

FIG. 15 is a functional block diagram showing a typical structure of the audio processing apparatus 20-2 as the second embodiment of the present disclosure. As shown in FIG. 15, the audio processing apparatus 20-2 as the second embodiment is made up of an operation portion 24, a microphone 25, earphones 26, a display portion 28, a control portion 210, a test tone generation circuit 220, a storage portion 230, an audio reproduction circuit 240, an equalizer 250, and a noise canceling sound generation circuit 260.

Many parts of the audio processing apparatus 20-2 as the second embodiment are substantially the same as those of the audio processing apparatus 20-1 as the first embodiment. For that reason, the ensuing explanation will stress the structural differences between the second embodiment and the first embodiment.

The microphone 25 (sound pickup portion) picks up the ambient sound of the audio processing apparatus 20-2. The microphone 25 is positioned close to the earphones 26 in order to implement noise cancellation. For example, the microphone 25 may be contained inside the enclosures constituting the earphones.

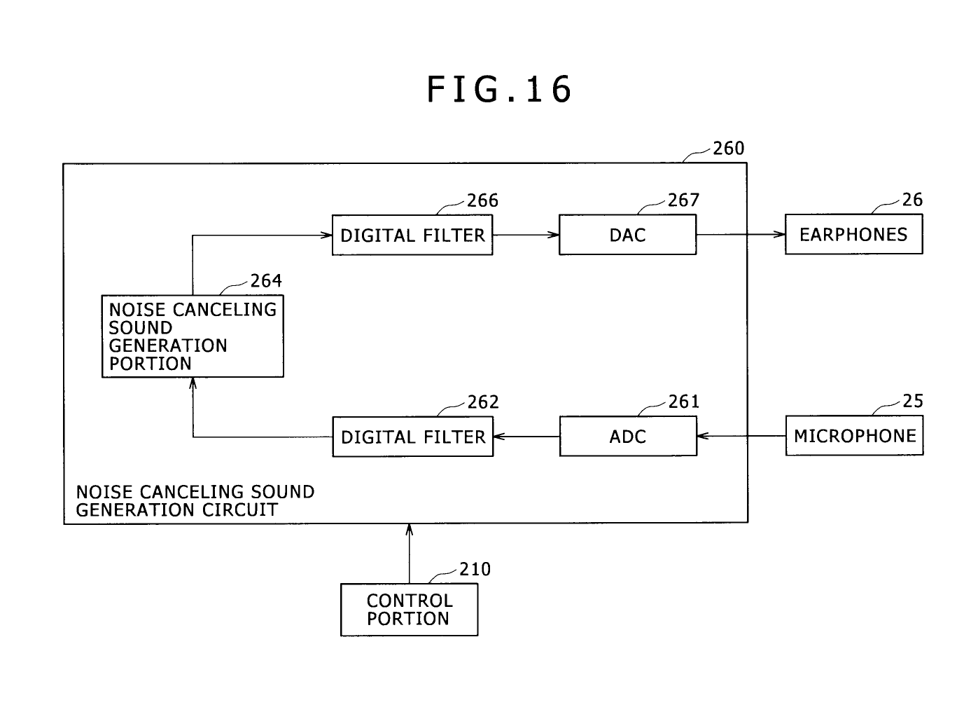

Based on the ambient sound picked up by the microphone 25, the noise canceling sound generation circuit 260 (second signal generation portion) generates a noise canceling sound (ambient sound reduction signal) for reducing the ambient sound at the locations where the user perceives sounds. A typical structure of the noise canceling sound generation circuit 260 is explained below in reference FIG. 16.

FIG. 16 is an explanatory view showing a typical structure of the noise canceling sound generation circuit 260. As shown in FIG. 16, the noise canceling sound generation circuit 260 includes an analog-digital converter (ADC) 261, a digital filter 262, a noise canceling sound generation portion 264, a digital filter 266, and a digital-analog converter (DAC) 267.

The ADC 261 is supplied with a sound pickup signal representative of the ambient sound from the microphone 25 and converts the supplied pickup signal from analog to digital form.

The digital filter 262 adjusts the frequency characteristic of the sound pickup signal converted to digital form by the ADC 261 in accordance with a control signal from the control portion 210. The noise canceling sound generation portion 264 generates a noise canceling sound whose phase is opposite to that of the sound pickup signal fed from the digital filter 262. The noise canceling sound generation portion 264 may adopt any suitable method for generating the noise canceling sound.

The digital filter 266 adjusts the frequency characteristic of the noise canceling sound generated by the noise canceling sound generation portion 264 in accordance with a control signal from the control portion 210. The controls exercised by the control portion 210 will be discussed later.

The DAC 267 converts the noise canceling sound fed from the digital filter 266 from digital to analog form. The noise canceling sound converted to analog form by the DAC 267 is sent to the earphones 26 for output.

### (Noise Canceling During Hearing Characteristic Tests)

With the second embodiment, the noise canceling sound generation portion 264 under control of the control portion 210 can boost the accuracy of hearing characteristic tests. Specifically, the control portion 210 operates the noise canceling sound generation portion 264 during a hearing characteristic test, i.e., while a test tone is being output. This structure permits more accurate acquisition of the user's hearing characteristics because the hearing characteristic tests are carried out while the influence of the external noise is being suppressed.

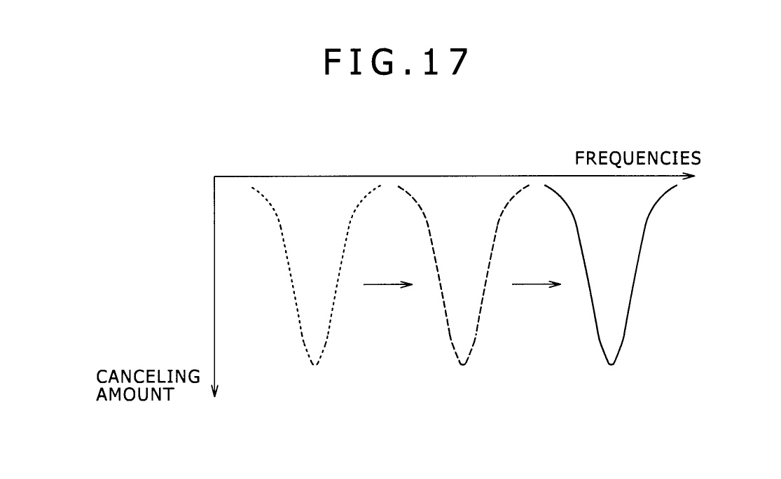

Furthermore, the control portion 210 may vary the filter characteristic of the digital filter 266 in keeping with the frequency changes of the test tone generated by the test tone generation circuit 220. For example, the control portion 210 may allow the digital filter 266 selectively to pass or emphasize that frequency component in the noise canceling sound which is the same as the frequency of the test tone. More specifically, if the test tone frequency is Fx, the control portion 210 may let pass the frequency band component containing the frequency Fx of the noise canceling sound and cut off the other frequency band components. Explained below in reference to FIG. 17 is a specific example of the noise canceling sound frequency characteristic acquired under such control of the control portion 210.

FIG. 17 is an explanatory view showing how the frequency characteristic of a noise canceling sound is typically varied. If the frequency of the test tone generated by the test tone generation circuit 220 is monotonically increasing as shown in FIG. 5, the noise canceling sound generation circuit 260 shifts the frequency band of the noise canceling sound gradually toward the high frequency side. This structure helps prevent the test tone from being buried in the noise component because the noise component in the frequency of the test tone being output is reduced.

The foregoing paragraphs discussed the example in which the control portion 210 varies the filter characteristic of the digital filter 266 in order to adjust the frequency characteristic of the noise canceling sound. Alternatively, the control portion 210 may vary the filter characteristic of the digital filter 262 so as to adjust the frequency characteristic of the noise canceling sound. Also, the noise canceling sound generation portion 264 may generate the noise canceling sound while adjusting its frequency characteristic in accordance with the frequency changes in the test tone.

### (Noise Canceling During Audio Data Reproduction)

The control portion 210 may also operate the noise canceling sound generation circuit 260 during audio data reproduction. In this case, the earphones 26 output the reproduced signal corrected by the equalizer 250 in keeping with the user's hearing characteristic information, as well as the noise canceling sound generated by the noise canceling sound generation circuit 260.

Furthermore, the control portion 210 may control the operation of the noise canceling sound generation circuit 260 in accordance with the user's hearing characteristic information. For example, if the external noise picked up by the microphone 25 has a frequency that is difficult for the user to hear, the control portion 210 may cause the noise canceling sound generation circuit 260 to reduce its noise canceling amount or may turn off the noise canceling sound generation circuit 260 altogether. This structure helps reduce the power dissipation involved in noise canceling.

On the other hand, if the control portion 210 does not operate the noise canceling sound generation circuit 260 during audio data reproduction, the control portion 210 may cause the equalizer 250 to correct the reproduced signal in keeping with the external noise picked up by the microphone 25 in addition to the user's hearing characteristic information. For example, the control portion 210 may cause the equalizer 250 to emphasize the reproduced signal on the frequency band of the external noise. This structure allows the user to perceive the sound image of audio data more clearly even if the noise canceling sound generation circuit 260 is not in operation.

### 4. THIRD EMBODIMENT

The foregoing paragraphs discussed the audio processing apparatus 20-2 as the second embodiment of the present disclosure. What follows is an explanation of an audio processing apparatus 20-3 practiced as the third embodiment of the present disclosure. As will be discussed below in detail, the audio processing apparatus 20-3 as the third embodiment is capable of enhancing the user's awareness of his or her hearing characteristics.

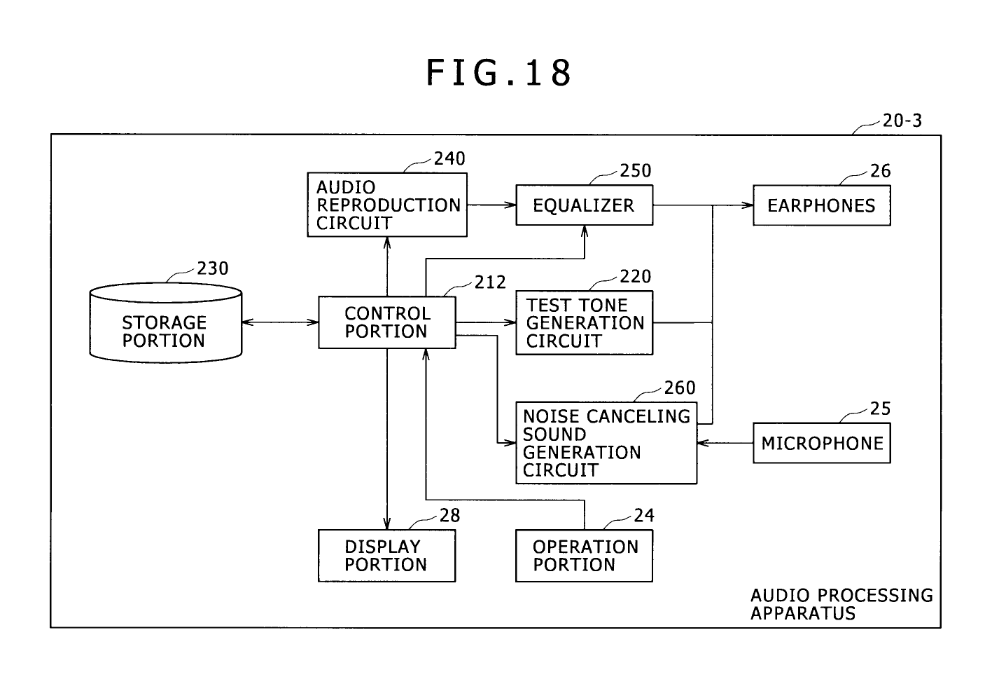

FIG. 18 is a functional block diagram showing a typical structure of the audio processing apparatus 20-3 practiced as the third embodiment of the present disclosure. As shown in FIG. 18, the audio processing apparatus 20-3 as the third embodiment is made up of an operation portion 24, a microphone 25, earphones 26, a display portion 28, a control portion 212, a test tone generation circuit 220, a storage portion 230, an audio reproduction circuit 240, an equalizer 250, and a noise canceling sound generation circuit 260.

Many parts of the audio processing apparatus 20-3 as the third embodiment are substantially the same as those of the audio processing apparatus 20-2 as the second embodiment. For that reason, the ensuing explanation will stress the structural differences between the third embodiment and the second embodiment.

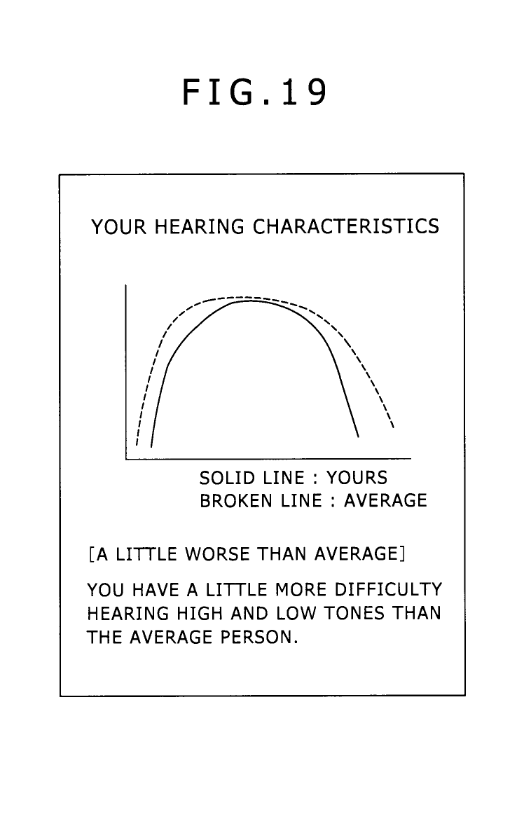

The control portion 212 of the third embodiment possesses not only the function of the control portion 210 in the above-described first and second embodiments but also the function of generating a screen for enhancing the user's awareness of his or her hearing characteristics and of causing the display portion 28 to display the generated screen. For example, as shown in FIG. 19, the display portion 212 may cause the display portion 28 to display a screen reflecting the results of the hearing characteristic tests taken by the user.

FIG. 19 is an explanatory view showing a specific example of hearing characteristic test results displayed on the screen of the display portion 28. As shown in FIG. 19, the screen showing hearing characteristic test results includes a graphic representation illustrating the difference between the user's hearing characteristics (in solid line) and the average hearing characteristic (in broken line), along with a message explaining specifics of the user's hearing characteristics. By checking such a screen showing the hearing characteristic test results, the user can accurately grasp his or her own hearing characteristics.

It has been found that users who hear sounds with relatively high sound volumes tend to have their hearing characteristics worsened. Given such findings, the control portion 212 may provide the user when hearing sounds with a relatively large sound volume with a screen displayed on the display portion 28 prompting the user to take hearing characteristic tests. For example, based on the user's past history of sound volumes in effect during audio reproduction, the control portion 212 may calculate indexes regarding the reproduced sound volumes such as the average of the actual sound volumes reproduced and the frequency with which sounds were reproduced with volumes exceeding a predetermined threshold. If these indexes are found to exceed predetermined settings, the control portion 212 may cause the display portion 28 to display the screen prompting the user to take hearing characteristic tests. As another alternative, when the user is hearing sounds with a relatively high sound volume, the control portion 212 may act to reduce the sound volume of the reproduced audio data.

### 5. VARIATIONS

It is to be understood that while the disclosure has been described in conjunction with specific embodiments with reference to the accompanying drawings, it is evident that many alternatives, modifications and variations will become apparent to those skilled in the art in light of the foregoing description. It is thus intended that the present disclosure embrace all such alternatives, modifications and variations as fall within the spirit and scope of the appended claims.

For example, where the earphones 26 are composed of a right-ear phone (right-ear audio output portion) and a left-ear phone (left-ear audio output portion), hearing characteristic tests may be carried out separately on the user's right ear and left ear. This structure permits acquisition of hearing characteristic information separately on the right ear and left ear and allows the acquired information to be stored separately into the storage portion 230. The equalizer 250 can then correct the reproduced signal for the right ear based on the right-ear hearing characteristic information and the reproduced signal for the left ear on the basis of the left-ear hearing characteristic information.

Also, the storage portion 230 may be arranged to store the audio data based on the reproduced signal corrected by the equalizer 250. This structure eliminates the need for correcting the audio data as it is reproduced based on the user's hearing characteristic information. If such audio data is moved from this audio processing apparatus to another audio processing apparatus, the latter apparatus can output the reproduced signal having been corrected on the basis of the user's hearing characteristic information.

The audio processing apparatus 20 may be further provided with a communication portion for transmitting to another audio processing apparatus the user's hearing characteristic information acquired through hearing characteristic tests. Upon receipt of the user's hearing characteristic information thus transmitted, the other audio processing apparatus can also correct the reproduced signal based on the user's information. If the storage portion 230 is a piece of removable storage media, then the movement of hearing characteristic information to another audio processing apparatus may be accomplished by attaching the removed storage portion 230 carrying the information in question to the other apparatus.

### 6. CONCLUSION

The first embodiment of the present disclosure uses test tones of which the frequencies are varied over time during hearing characteristic tests. This embodiment provides the user with freshly inspired hearing characteristic tests and can shorten the time it takes to carry out the tests. The second embodiment of the present disclosure suppresses the influence of external noise when hearing characteristic tests are performed. This embodiment permits more accurate acquisition of the user's hearing characteristic information than before. The third embodiment of the present disclosure allows the display portion 28 to display the screen showing hearing characteristic test results as well as the screen for urging the execution of the hearing characteristic tests. This helps enhance the user's awareness of his or her own hearing characteristics.

In this description, the steps constituting the processes executed by the audio processing apparatus 20 of the present disclosure need not necessarily be performed chronologically, i.e., in the order in which they are depicted in the accompanying flowcharts. Alternatively, these steps may be carried out by the audio processing apparatus 20 parallelly or in sequences different from those given by the flowcharts.

According to the embodiment of the present disclosure, it is also possible to create a computer program for causing the hardware such as the CPU (Central Processing Unit), ROM and RAM (Random Access Memory) inside the audio processing apparatus 20 to exert functions equivalent to those of the above-described components making up the audio processing apparatus 20. It is further possible to offer storage media carrying that computer program.

The present application contains subject matter related to that disclosed in Japanese Priority Patent Application JP 2010-181269 filed in the Japan Patent Office on Aug. 13, 2010, the entire content of which is hereby incorporated by reference.

It should be understood by those skilled in the art that various modifications, combinations, sub-combinations and alterations may occur depending on design requirements and other factor in so far as they are within the scope of the appended claims or the equivalents thereof.

What is claimed is:

1. An audio processing apparatus comprising:
a first signal generation portion configured to generate an audio signal of which the frequency is varied over time;
an operation portion;
a storage portion configured to store characteristic information in accordance with the frequency and amplitude of said audio signal in effect when said operation portion is operated;
a reproduction portion configured to reproduce audio data; and
a correction portion configured to correct a reproduced signal from said reproduction portion based on said characteristic information stored in said storage portion.

2. The audio processing apparatus according to claim 1, further comprising:
a sound pickup portion;
a second signal generation portion configured to generate an ambient sound reduction signal for reducing an ambient sound based on the pickup of said ambient sound by said sound pickup portion; and
a control portion configured to control said second signal generation portion in operation;
wherein said control portion operates said second signal generation portion while said first signal generation portion is being caused to generate said audio signal.

3. The audio processing apparatus according to claim 2, wherein said second signal generation portion generates said ambient sound reduction signal different in frequency characteristic from said ambient sound in accordance with the frequency of said audio signal generated by said first signal generation portion.

4. The audio processing apparatus according to claim 3, wherein said second signal generation portion generates said ambient sound reduction signal in a manner rendering said ambient sound lower on the same frequency band as said audio signal generated by said first signal generation portion than on other frequency bands.

5. The audio processing apparatus according to claim 4, wherein said first signal generation portion generates said audio signal of which not only the frequency but also the amplitude is varied over time.

6. The audio processing apparatus according to claim 5, wherein said control portion controls whether or not to operate said second signal generation portion upon reproduction of said audio data by said reproduction portion.

7. The audio processing apparatus according to claim 6, wherein, if said second signal generation portion does not generate said ambient sound reduction signal, said correction portion corrects said reproduced signal from said reproduction portion in accordance with said characteristic information stored in said storage portion and in keeping with said ambient sound picked up by said sound pickup portion.

8. The audio processing apparatus according to claim 7, wherein said correction portion emphasizes said reproduced signal on the same frequency band as said ambient sound.

9. The audio processing apparatus according to claim 2, wherein, when operating upon reproduction of said audio data by said reproduction portion, said second signal generation portion generates said ambient sound reduction signal based on said characteristic information stored in said storage portion.

10. The audio processing apparatus according to claim 3, further comprising a left-ear audio output portion and a right-ear audio output portion;
wherein said storage portion stores left-ear characteristic information and right-ear characteristic information; and
said correction portion corrects the reproduced signal output to said left-ear audio output portion in accordance with said left-ear characteristic information and the reproduced signal output to said right-ear audio output portion in keeping with said right-ear characteristic information.

11. The audio processing apparatus according to claim 3, further comprising a display portion configured to display a screen in accordance with said characteristic information having been acquired.

12. The audio processing apparatus according to claim 3, wherein said storage portion stores said audio data based on said reproduced signal having undergone the correction by said correction portion.

13. A program for causing a computer to function as an apparatus comprising:
a first signal generation portion configured to generate an audio signal of which the frequency is varied over time;
an operation portion;
a storage portion configured to store characteristic information in accordance with the frequency and amplitude of said audio signal in effect when said operation portion is operated;
a reproduction portion configured to reproduce audio data; and
a correction portion configured to correct a reproduced signal from said reproduction portion based on said characteristic information stored in said storage portion.

14. An audio processing method comprising:
generating an audio signal of which the frequency is varied over time;
storing onto a storage medium characteristic information in accordance with the frequency and an amplitude of said audio signal in effect when a user performs an operation;
reproducing audio data; and
correcting a reproduced signal of said audio data based on said characteristic information stored on said storage medium.
